(19) United States
(12) Patent Application Publication
(10) Pub. No.: US 2026/0164897 A1
(43) Pub. Date: Jun. 11, 2026

(54) DISPLAY PANEL AND MANUFACTURING METHOD THEREOF

(71) Applicant: AUO Corporation, Hsinchu City (TW)

(72) Inventors: Yi-Sheng Jhao, Hsinchu City (TW); Kuan-Hsun Chen, Hsinchu City (TW)

(73) Assignee: AUO Corporation, Hsinchu City (TW)

(21) Appl. No.: 19/230,053

(22) Filed: Jun. 5, 2025

(30) Foreign Application Priority Data
Dec. 9, 2024 (TW) 113147746

(51) Int. Cl. H10H 29/853; H10H 29/01

(52) U.S. Cl. CPC H10H 29/853; H10H 29/012

(57) ABSTRACT

Provided is a display panel, which includes a substrate, multiple light emitting elements, an opaque adhesive layer and a first transmissive adhesive layer. The light emitting elements are disposed on a first surface of the substrate. The opaque adhesive layer is located on the first surface of the substrate and overlays multiple side surfaces of a portion of the light emitting elements. The first transmissive adhesive layer is located on the first surface of the substrate and is connected to the opaque adhesive layer. The first transmissive adhesive layer overlays multiple side surfaces of another portion of the light emitting elements. The opaque adhesive layer includes a slope section connected to the first transmissive adhesive layer. A length of the slope section is between 0.1 millimeters and 2 millimeters.

### CROSS-REFERENCE TO RELATED APPLICATION

This application claims the priority benefit of Taiwan application serial no. 113147746, filed on Dec. 9, 2024. The entirety of the above-mentioned patent application is hereby incorporated by reference herein and made a portion of this specification.

### BACKGROUND

### Technical Field

The disclosure relates to a display technology and a manufacturing method, and particularly relates to a display panel and a manufacturing method thereof.

### Related Art

Recently, light-emitting diode display panels have gradually gained popularity due to advantages such as easy color adjustment, long light emission lifetime, and fast response time. With the diverse changes in market demand, a structural design combining a transmitting display and a non-transmitting display has been proposed. Generally, a method for manufacturing such displays is to align the edges of a transmitting display and a non-transmitting display by laser and then splice the two together. However, this manufacturing manner needs high accuracy of laser cutting, and the edges of the two displays need to be vertical and accurately aligned and spliced, otherwise obvious splicing seams may appear. How to prevent splicing seams from being generated during the manufacturing of such displays is one of the topics that related manufacturers wish to solve.

### SUMMARY

The disclosure provides a display panel, in which a transmitting region and non-transmitting region are tightly connected.

The disclosure provides a method of manufacturing a display panel, in which a transmitting region and a non-transmitting region are tightly connected without having seams, which can solve the problem of having obvious splicing seams at a junction between the transmitting region and the non-transmitting region.

The display panel of the disclosure includes a substrate, multiple light emitting elements, an opaque adhesive layer, and a first transmissive adhesive layer. The light emitting elements are disposed on a first surface of the substrate. The opaque adhesive layer is located on the first surface of the substrate and overlays multiple side surfaces of a portion of the light emitting elements. The first transmissive adhesive layer is located on the first surface of the substrate and connected to the opaque adhesive layer. The first transmissive adhesive layer overlays multiple side surfaces of another portion of the light emitting elements. The opaque adhesive layer includes a slope section connected to the first transmissive adhesive layer.

The method of manufacturing a display panel of the disclosure includes: multiple light emitting elements are disposed on a first surface of a substrate, an opaque adhesive layer is packaged on the first surface of the substrate, a first transmissive adhesive layer is packaged on the first surface of the substrate, and an etching process is executed to etch the opaque adhesive layer and the first transmissive adhesive layer to expose the light emitting elements. The opaque adhesive layer overlays a portion of the light emitting elements. The opaque adhesive layer includes a slope section. The first transmissive adhesive layer is connected to the slope section of the opaque adhesive layer and overlays another portion of the light emitting elements. A length of the slope section is between 0.1 millimeters and 2 millimeters.

Based on the above, in the display panel according to an embodiment of the disclosure, the opaque adhesive layer and the first transmissive adhesive layer are located on the substrate to form a transmitting region and a non-transmitting region. The opaque adhesive layer is tightly connected to the first transmissive adhesive layer through the slope section. In this way, the transmitting region and the non-transmitting region may have no seams, which can prevent the problem of generating splicing seams due to insufficient cutting and splicing accuracy. In addition, the display panel of the embodiment may adjust a ratio of the transmitting region and the non-transmitting region during a lamination of the opaque adhesive layer and the first transmissive adhesive layer without changing an arrangement design, thereby having better process flexibility.

### BRIEF DESCRIPTION OF THE DRAWINGS

FIG. 1 is a schematic top view of a display panel according to an embodiment of the disclosure.

FIG. 2A is a schematic cross-sectional view along the sectional line A-A in FIG. 1.

FIG. 2B is a schematic cross-sectional view along the sectional line B-B in FIG. 1.

FIG. 2C is a schematic cross-sectional view along the sectional line C-C in FIG. 1.

FIG. 3A to FIG. 3E are schematic cross-sectional views of a manufacturing process of the display panel in FIG. 1.

FIG. 4 is a block diagram of a manufacturing process of the display panel in FIG. 1.

### DESCRIPTION OF THE EMBODIMENTS

As used herein, “about,” “approximately” or “substantially” includes the values as mentioned and the average values within the range of acceptable deviations that can be determined by those of ordinary skill in the art. Consider to the specific amount of errors related to the measurements (that is, the limitations of the measurement system), the meaning of “about” may be, for example, referred to a value within one or more standard deviations of the value, or within ±30%, ±20%, ±10%, ±5%. Furthermore, the “about,” “approximately” or “substantially” used herein may be based on the optical property, etching property or other properties to select a more acceptable deviation range or standard deviation, but may not apply one standard deviation to all properties.

In the drawings, the thickness of layers, films, panels, regions, etc., are exaggerated for clarity's sake. The same reference numerals refer to the same elements throughout the specification. It will be understood that when a component such as a layer, a film, a region, or a substrate is referred to be “on” or “connected to” another component, it may be directly on or connected to the other another component, or intermediate components may also exist there between. Comparatively, when a component is referred to be “directly on” or “directly connected” to another, none other intermediate component exits there between. As used herein, the “connection” may refer to physical and/or electrical connection. Furthermore, “electrical connection” of two components may refer to that other components may exist between the two components.

Moreover, relative terms such as “under” or “bottom” and “above” or “top” may be used for describing a relationship of one element and another element as that shown in figures. It should be noted that the relative terms are intended to include a different orientation of the device besides the orientation shown in the figure. For example, if a device in a figure is flipped over, the element originally described to be located “under” other element is oriented to be located “above” the other element. Therefore, the illustrative term “under” may include orientations of “under” and “on”, which is determined by the specific orientation of the figure. Similarly, if a device in a figure is flipped over, the element originally described to be located “below” or “underneath” other element is oriented to be located “on” the other element. Therefore, the illustrative term “under” or “below” may include orientations of “above” and “under”.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

The exemplary embodiment is described below with reference of a cross-sectional view of a schematic diagram of an idealized embodiment. Therefore, a shape change of the figure serving as a result of manufacturing techniques and/or tolerances may be expected. Therefore, the embodiment of the disclosure should not be construed as limited to a particular shape of a region as shown herein, but includes a shape deviation caused by manufacturing tolerance. For example, a shown or described flat area may generally have rough and/or non-linear features. Moreover, a shown acute angle may be round. Therefore, a region shown in the figure is essentially schematic, and a shape thereof is not intended to show an accurate shape of the region, and is not intended to limit a range of the claims of the disclosure.

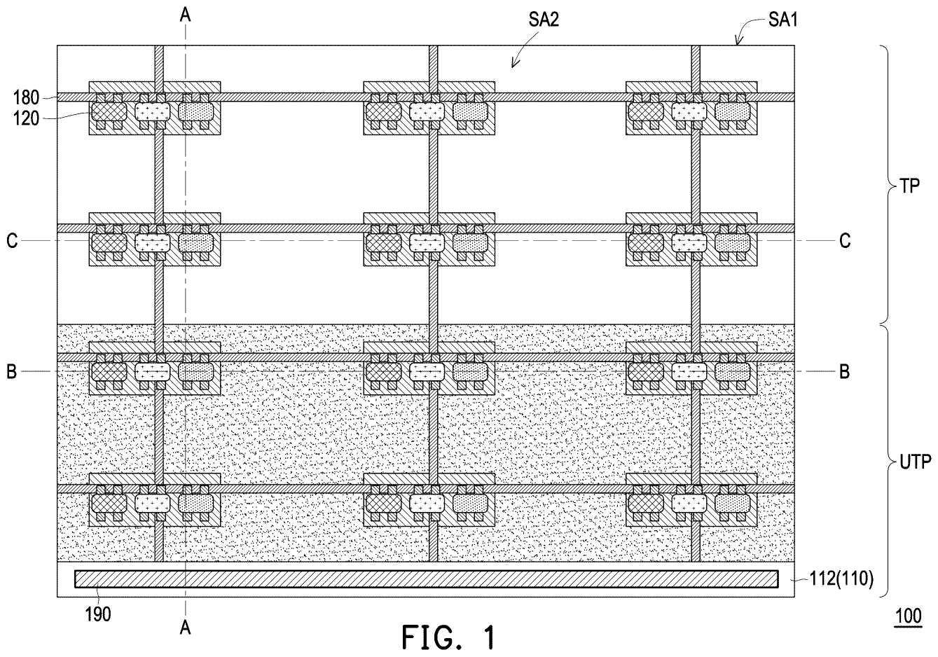

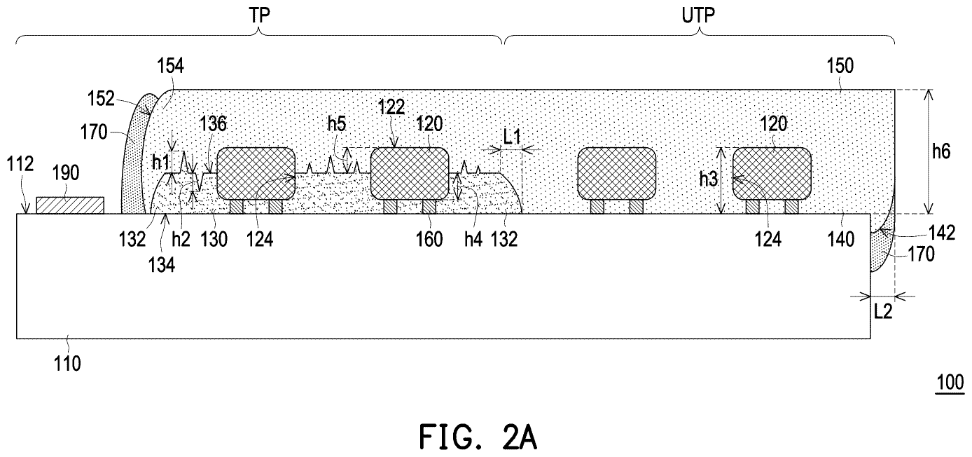

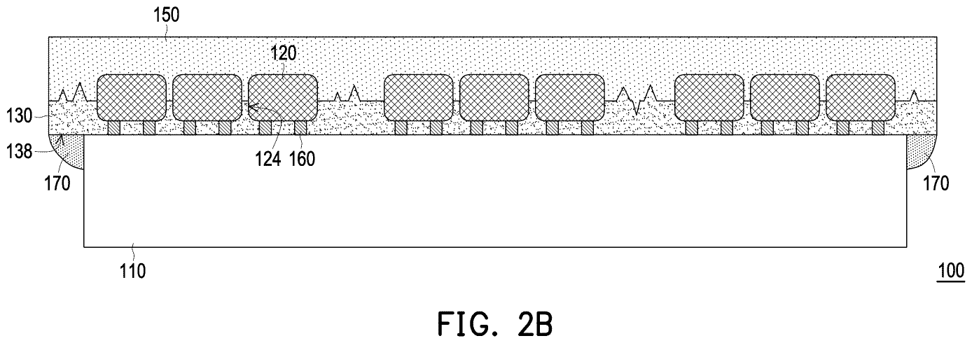

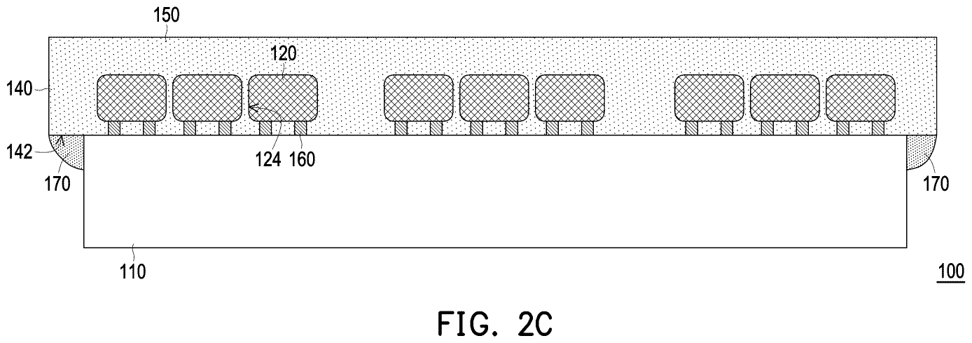

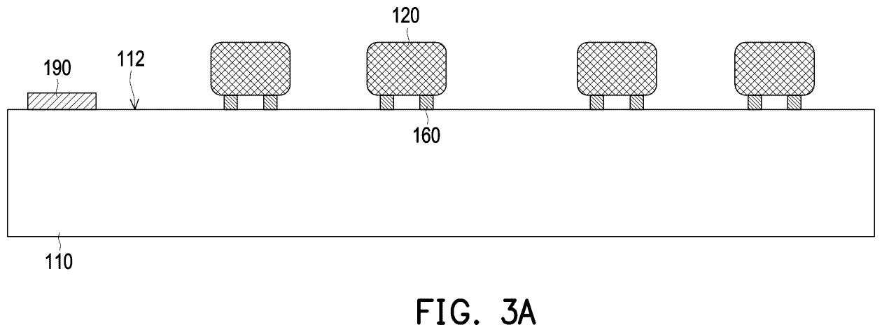

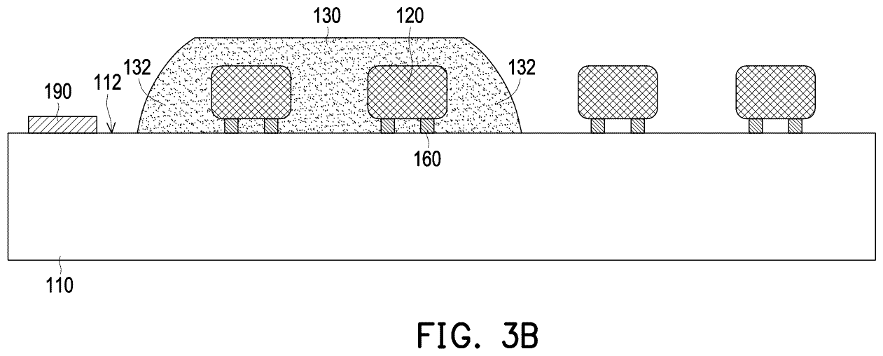

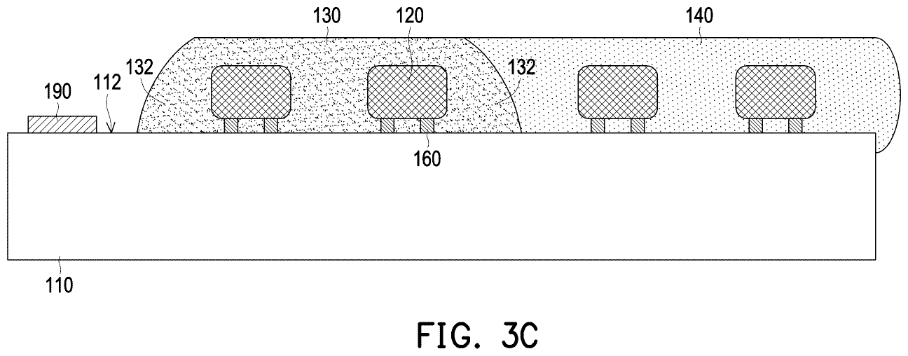

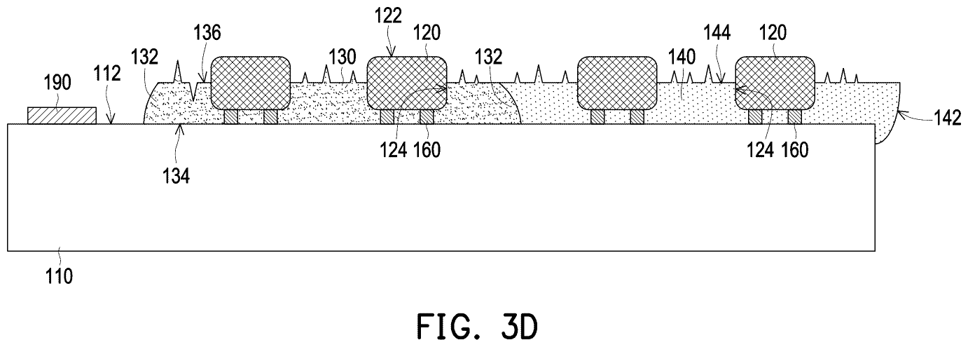

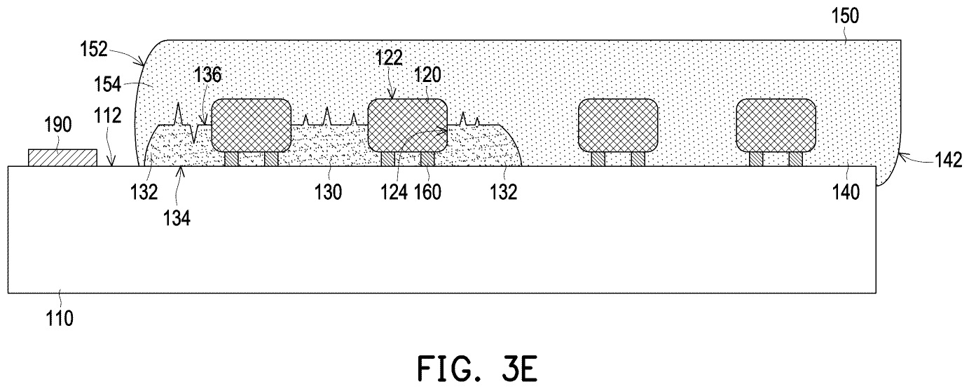

FIG. 1 is a schematic top view of a display panel according to an embodiment of the disclosure. FIG. 2A is a schematic cross-sectional view along the sectional line A-A in FIG. 1. FIG. 2B is a schematic cross-sectional view along the sectional line B-B in FIG. 1. FIG. 2C is a schematic cross-sectional view along the sectional line C-C in FIG. 1. FIG. 3A to FIG. 3E are schematic cross-sectional views of a manufacturing process of the display panel in FIG. 1. It should be noted first that, to keep the drawings neat, FIG. 1 does not illustrate a water-blocking adhesive 170 shown in FIG. 2A to FIG. 2C, and FIG. 2A to FIG. 3E do not illustrate a trace 180 shown in FIG. 1. In addition, a quantity of light emitting elements 120 and an arrangement manner illustrated in FIG. 1 to FIG. 3E are for indication purposes. In practice, more light emitting elements 120 may be included, and the arrangement manner is not limited thereto.

Please refer to FIG. 1 to FIG. 3E. A display panel 100 is the display panel 100 including a transmitting region TP and a non-transmitting region UTP, and may be configured for fighter jet instruments or household appliances, etc. However, the disclosure is not limited thereto. The display panel 100 of the embodiment includes a substrate 110, multiple light emitting elements 120, an opaque adhesive layer 130, and a first transmissive adhesive layer 140.

The multiple light emitting elements 120 are connected to a first surface 112 of the substrate 110 through multiple pads 160. The multiple light emitting elements 120 are connected to each other through multiple traces 180. A height h3 of the light emitting element 120 and the pad 160 is, for example, about 6.9 microns. Specifically, after the multiple light emitting elements 120 are first formed on one or more growth substrates (not illustrated), mass transfer technology may be utilized to dispose the multiple light emitting elements 120 on the first surface 112 of the substrate 110 (as shown in FIG. 3A). The substrate 110 is a transparent substrate and may include the multiple traces 180 (signal lines such as data lines, scan lines, or power lines), at least one driving circuit chip (not illustrated), and another pad 190. The driving circuit chip has, for example, transistors or integrated circuits (ICs) and is electrically connected to the multiple light emitting elements 120 through the pads 160, and controls display signals of the multiple light emitting elements 120 to provide a display screen. The pad 190 is, for example, located on one side of the first surface 112 and may be connected to other functional elements (not illustrated) to allow the other functional elements to control the display panel 100.

The multiple light emitting elements 120 include, for example, micro light emitting diodes (micro-LEDs) of different colors, such as red light emitting diodes, green light emitting diodes, and blue light emitting diodes, etc. However, the disclosure is not limited thereto. As shown in FIG. 1, one set of the light emitting elements 120 is, for example, arranged in an order of red light emitting diodes, green light emitting diodes, and blue light emitting diodes. All of the light emitting elements 120 are, for example, arranged in an array in the same light emission color order on the first surface 112 of the substrate 110.

In addition, a projection area SA2 of the light emitting elements 120 and the multiple traces 180 on the first surface 112 of the substrate 110 occupies between 10% and 70% of an area SA1 of the first surface 112 to allow a combination thereof to be a transparent display. Through the foregoing value definition and the design of the light emitting elements 120 arranged in the same order, the display panel 100 of the embodiment may determine a ratio of the transmitting region TP and the non-transmitting region UTP during a lamination of the opaque adhesive layer 130 and the first transmissive adhesive layer 140 (which will be described in detail later). In other words, the display panel 100 of the embodiment does not need to determine the ratio of the transmitting region TP and the non-transmitting region UTP when the substrate 110 is being manufactured, thereby having better process flexibility.

The opaque adhesive layer 130 is located on the first surface 112 of the substrate 110 and overlays multiple side surfaces 124 of a portion of the light emitting elements 120. The opaque adhesive layer 130 includes a slope section 132, a second surface 134, and a third surface 136. A length L1 of the slope section 132 is between 0.1 millimeters and 2 millimeters. The second surface 134 and the third surface 136 are disposed opposite to each other. The second surface 134 is connected to the first surface 112 of the substrate 110. The third surface 136 is away from the first surface 112 of the substrate 110 and is a rough surface. The rough surface of the third surface 136 has, for example, a surface with protrusions and recesses. A protrusion height h1 and a recess depth h2 of the rough surface are between 0.01 microns and 0.5 microns. In addition, the first transmissive adhesive layer 140 is located on the first surface 112 of the substrate 110 and is connected to the slope section 132 on one side of the opaque adhesive layer 130. The first transmissive adhesive layer 140 overlays multiple side surfaces 124 of another portion of the light emitting elements 120.

In detail, the opaque adhesive layer 130 is first laminated to the substrate 110 having the light emitting elements 120 through a release film (not illustrated) to overlay a portion of the light emitting elements 120 (as shown in FIG. 3B). A region of the substrate 110 overlaid by the opaque adhesive layer 130 is the non-transmitting region UTP. During a process of lamination, due to factors such as overflow during lamination, an edge of the opaque adhesive layer 130 is allowed to form the slope section 132.

After the opaque adhesive layer 130 is laminated to the substrate 110, the first transmissive adhesive layer 140 is then laminated to the substrate 110 through a release film (not illustrated) to overlay another portion of the light emitting elements 120. A region of the substrate 110 overlaid by the first transmissive adhesive layer 140 is the transmitting region TP. At this time, the first transmissive adhesive layer 140 is laminated and tightly connected to the slope section 132 on one side of the opaque adhesive layer 130 (as shown in FIG. 3C).

Afterwards, the opaque adhesive layer 130 and the first transmissive adhesive layer 140 are etched at the same time through an etching process until the heights thereof are lower than multiple top surfaces 122 of the multiple light emitting elements 120 (as shown in FIG. 3D). The third surface 136 of the opaque adhesive layer 130 and the fourth surface 144 of the first transmissive adhesive layer 140 away from the substrate 110 are surfaces that are subjected to the etching process at the same time, therefore the third surface 136 and the fourth surface 144 are substantially equal in height, and both have rough surfaces with protrusions and recesses.

In addition, a distance h4 between the third surface 136 and the fourth surface 144 and the pad 160 is between 2 microns and 3 microns. A distance h5 between the third surface 136 and the fourth surface 144 and the multiple top surfaces 122 of the multiple light emitting elements 120 is between 1 micron and 3.5 microns. In other words, the etched third surface 136 and fourth surface 144 need to be lower than the top surfaces 122 of the light emitting elements 120 to allow the opaque adhesive layer 130 and the first transmissive adhesive layer 140 to only overlay the side surfaces 124 of a portion of the light emitting elements 120, thereby allowing light from the light emitting elements 120 to be properly emitted outward. In addition, the third surface 136 and the fourth surface 144 also need to be higher than the pad 160 to allow the opaque adhesive layer 130 and the first transmissive adhesive layer 140 to clad the pad 160, which may prevent the pad 160 and the electrode (not illustrated) from being damaged by an etching agent, thereby affecting the operation of the light emitting elements 120.

As described above, after the opaque adhesive layer 130 is first laminated to the substrate 110, and then the first transmissive adhesive layer 140 is laminated to the substrate 110, thereby forming the transmitting region TP and the non-transmitting region UTP. The opaque adhesive layer 130 and the first transmissive adhesive layer 140 are tightly connected to allow a junction between the transmitting region TP and the non-transmitting region UTP to have no seams. This manufacturing manner is relatively simple and can prevent the problem of generating splicing seams due to insufficient cutting and splicing accuracy.

In addition, the display panel 100 of the embodiment determines the ratio of the transmitting region TP and the non-transmitting region UTP through a ratio of the opaque adhesive layer 130 and the first transmissive adhesive layer 140 laminated to the first surface 112 of the substrate 110. Therefore, the display panel 100 of the embodiment may adjust the ratio of the transmitting region TP and the non-transmitting region UTP during the lamination of the opaque adhesive layer 130 and the first transmissive adhesive layer 140 without changing the arrangement design, thereby having better process flexibility.

It should be noted that for the display panel 100, the opaque adhesive layer 130 needs to be first laminated to the substrate 110, and then the first transmissive adhesive layer 140 is laminated to the substrate 110. If the first transmissive adhesive layer 140 is first laminated to the substrate 110, and then the opaque adhesive layer 130 is laminated to the substrate 110, an edge 142 of the first transmissive adhesive layer 140 may first form a slope section (similar to the slope section 132), and the opaque adhesive layer 130 may be connected to the slope section. However, when the opaque adhesive layer 130 is laminated, the opaque adhesive layer 130 might overlay a portion of the light emitting elements 120 located in the first transmissive adhesive layer 140, thereby affecting the image display at the junction between the transmitting region TP and the non-transmitting region UTP.

The display panel 100 of the embodiment further includes a second transmissive adhesive layer 150 connected to the first transmissive adhesive layer 140. The second transmissive adhesive layer 150 is located on top of the opaque adhesive layer 130 and the first transmissive adhesive layer 140. A material of the first transmissive adhesive layer 140 is a same as a material of the second transmissive adhesive layer 150. The first transmissive adhesive layer 140 and the second transmitting layer 150 may have scattering particles. A material of the scattering particles may include inorganic transmissive materials, such as silicon dioxide (SiO₂). However, the disclosure is not limited thereto.

In detail, the second transmissive adhesive layer 150 is laminated on top of the opaque adhesive layer 130 and the first transmissive adhesive layer 140 through a release film (not illustrated) to be connect to the third surface 136 of the opaque adhesive layer 130 and the fourth surface 144 of the first transmissive adhesive layer 140 (as shown in FIG. 3E). Since the second transmissive adhesive layer 150 is laminated through a release film (not illustrated), an edge 152 of the second transmissive adhesive layer 150 also has a slope section 154. The slope section 154 clads the slope section 132 away from a junction between the opaque adhesive layer 130 and the first transmissive adhesive layer 140.

Since the material of the first transmissive adhesive layer 140 is the same as the material of the second transmissive adhesive layer 150, when looking from a direction of the second transmissive adhesive layer 150 toward the substrate 110, the rough surface of the fourth surface 144 of the first transmissive adhesive layer 140 may not be observed, and may not affect the visual experience. In addition, a total thickness h6 of the first transmissive adhesive layer 140 and the second transmissive adhesive layer 150 is between 15 microns and 50 microns to ensure the light emission effect of the light emitting elements 120 through the first transmissive adhesive layer 140 and the second transmissive adhesive layer 150 having scattering particles, while preventing the problem of generating difficulties in replacing the light emitting elements 120 due to the first transmissive adhesive layer 140 and the second transmissive adhesive layer 150 being too thick.

Please refer to FIG. 1 to FIG. 2C. The edge 142 of the first transmissive adhesive layer 140 and the edge 152 of the second transmissive adhesive layer 150 are overlaid to the substrate 110 through the water-blocking adhesive 170. Specifically, the edge 142 of the first transmissive adhesive layer 140 is connected to the substrate 110, and the water-blocking adhesive 170 may be disposed at a junction of the two to overlay a portion of the substrate 110 (as shown in FIG. 2A and FIG. 2C). The edge 152 of the second transmissive adhesive layer 150 is connected to the substrate 110, and the water-blocking adhesive 170 may be disposed at a junction of the two to overlay a portion of the substrate 110 (as shown in FIG. 2A). A lower edge 138 of the opaque adhesive layer 130 that is not overlaid by the second transmissive adhesive layer 150 is connected to the substrate 110, and the water-blocking adhesive 170 may be disposed at a junction of the two to overlay a portion of the substrate 110 (as shown in FIG. 2B). The water-blocking adhesive 170 is the transparent water-blocking adhesive 170. A length L2 thereof is, for example, between 10 microns and 5000 microns.

That is to say, the water-blocking adhesive 170 may be disposed at the surrounding where the opaque adhesive layer 130, the first transmissive adhesive layer 140, and the second transmissive adhesive layer 150 are connected to the substrate 110 to prevent moisture in the air from entering through the foregoing junctions, thereby preventing damage to the light emitting elements 120 and electronic elements (not illustrated) disposed on the first surface 112 of the substrate 110.

The following will provide an exemplary description of a method of manufacturing the display panel 100.

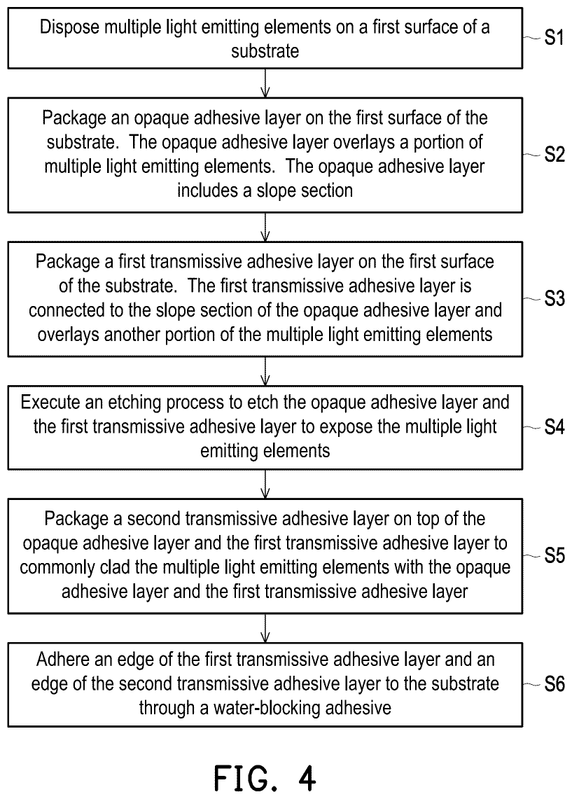

FIG. 4 is a block diagram of a manufacturing process of the display panel in FIG. 1. Please refer to FIG. 2A to FIG. 4. First, the multiple light emitting elements 120 are disposed on the first surface 112 of the substrate 110 (that is, step S1 in FIG. 4), as shown in FIG. 3A. Specifically, the multiple light emitting elements 120 utilizes, for example, mass transfer technology to be disposed on the first surface 112 of the substrate 110. However, the disclosure is not limited thereto. The multiple light emitting elements 120 are, for example, multiple micro light-emitting diodes. The multiple light emitting elements 120 are, for example, arranged in an array in a same light emitting color order on the first surface 112 of the substrate 110.

After a transfer of the multiple light emitting elements 120 is completed, the opaque adhesive layer 130 is packaged on the first surface 112 of the substrate 110. As shown in FIG. 3B, the opaque adhesive layer 130 overlays a portion of the multiple light emitting elements 120, and an edge of the opaque adhesive layer 130 includes the slope section 132 (that is, step S2 in FIG. 4). The length L1 of the slope section 132 is between 0.1 millimeters and 2 millimeters. Next, as shown in FIG. 3C, the first transmissive adhesive layer 140 is packaged on the first surface 112 of the substrate 110. The first transmissive adhesive layer 140 is connected to the slope section 132 on one side of the opaque adhesive layer 130 and overlays another portion of the multiple light emitting elements 120 (that is, step S3 in FIG. 4). A region where the opaque adhesive layer 130 overlays the substrate 110 is the non-transmitting region UTP. A region where the first transmissive adhesive layer 140 overlays the substrate 110 is the transmitting region TP.

As shown in FIG. 3D, after the opaque adhesive layer 130 and the first transmissive adhesive layer 140 are packaged on the substrate 110, an etching process is executed to etch the opaque adhesive layer 130 and the first transmissive adhesive layer 140 to expose the multiple light emitting elements 120 (that is, step S4 in FIG. 4). After the etching process is ended, as shown in FIG. 3E, the second transmissive adhesive layer 150 is packaged on top of the opaque adhesive layer 130 and the first transmissive adhesive layer 140 to commonly clad the multiple light emitting elements 120 with the opaque adhesive layer 130 and the first transmissive adhesive layer 140 (that is, step S5 in FIG. 4). Finally, the edge 142 of the first transmissive adhesive layer 140 and the edge 152 of the second transmissive adhesive layer 150 are adhered to the substrate 110 through the water-blocking adhesive 170. The lower edge 138 of the opaque adhesive layer 130 that is not overlaid by the second transmissive adhesive layer 150 is adhered to the substrate 110 through the water-blocking adhesive 170, thereby forming the display panel 100 shown in FIG. 1 to FIG. 2C (that is, step S6 in FIG. 4).

In summary, in the display panel according to an embodiment of the disclosure, the opaque adhesive layer and the first transmissive adhesive layer are located on the substrate to form the transmitting region and the non-transmitting region. The opaque adhesive layer is tightly connected to the first transmissive adhesive layer through the slope section. In this way, the transmitting region and the non-transmitting region may have no seams, which can prevent the problem of generating splicing seams due to insufficient cutting and splicing accuracy. In addition, the display panel of the embodiment may adjust the ratio of the transmitting region and the non-transmitting region during the lamination of the opaque adhesive layer and the first transmissive adhesive layer without changing the arrangement design, thereby having better process flexibility.

What is claimed is:

1. A display panel, comprising:
a substrate;
a plurality of light emitting elements, disposed on a first surface of the substrate;
an opaque adhesive layer, located on the first surface of the substrate and overlaying a plurality of side surfaces of a portion of the light emitting elements; and
a first transmissive adhesive layer, located on the first surface of the substrate and connected to the opaque adhesive layer, the first transmissive adhesive layer overlaying a plurality of side surfaces of another portion of the light emitting elements; wherein
the opaque adhesive layer comprises a slope section connected to the first transmissive adhesive layer.

2. The display panel according to claim 1, further comprising a second transmissive adhesive layer connected to the first transmissive adhesive layer, wherein the second transmissive adhesive layer is located on top of the opaque adhesive layer and the first transmissive adhesive layer.

3. The display panel according to claim 2, wherein a material of the first transmissive adhesive layer is a same as a material of the second transmissive adhesive layer.

4. The display panel according to claim 1, wherein the opaque adhesive layer comprises a second surface and a third surface disposed opposite to each other, the second surface is connected to the first surface of the substrate, and the third surface is a rough surface.

5. The display panel according to claim 4, wherein a protrusion height and a recess depth of the rough surface are between 0.01 microns and 0.5 microns.

6. The display panel according to claim 4, wherein the light emitting elements are connected to the substrate through a plurality of pads, the opaque adhesive layer and the first transmissive adhesive layer clad the pads, and a distance between the third surface and the pad is between 2 microns and 3 microns.

7. The display panel according to claim 4, wherein a distance between the third surface and a plurality of top surfaces of the light emitting elements is between 1 micron and 3.5 microns.

8. The display panel according to claim 2, wherein a total thickness of the first transmissive adhesive layer and the second transmissive adhesive layer is between 15 microns and 50 microns.

9. The display panel according to claim 2, wherein an edge of the first transmissive adhesive layer and an edge of the second transmissive adhesive layer are overlaid to the substrate through a water-blocking adhesive.

10. The display panel according to claim 1, wherein the light emitting elements are connected to each other through a plurality of traces, a projection area of the light emitting elements and the traces on the first surface of the substrate occupies between 10% and 70% of an area of the first surface.

11. The display panel according to claim 1, wherein a length of the slope section is between 0.1 millimeters and 2 millimeters.

12. A method of manufacturing a display panel, comprising:
disposing a plurality of light emitting elements on a first surface of a substrate;
packaging an opaque adhesive layer on the first surface of the substrate, wherein the opaque adhesive layer overlays a portion of the light emitting elements, and the opaque adhesive layer comprises a slope section;
packaging a first transmissive adhesive layer on the first surface of the substrate, wherein the first transmissive adhesive layer is connected to the slope section of the opaque adhesive layer and overlays another portion of the light emitting elements; and
executing an etching process to etch the opaque adhesive layer and the first transmissive adhesive layer to expose the light emitting elements, wherein
a length of the slope section is between 0.1 millimeters and 2 millimeters.

13. The method of manufacturing the display panel according to claim 12, further comprising:
packaging a second transmissive adhesive layer on top of the opaque adhesive layer and the first transmissive adhesive layer to commonly clad the light emitting elements with the opaque adhesive layer and the first transmissive adhesive layer.

14. The method of manufacturing the display panel according to claim 13, further comprising:
overlaying an edge of the first transmissive adhesive layer and an edge of the second transmissive adhesive layer to the substrate through a water-blocking adhesive after packaging the second transmissive adhesive layer on top of the opaque adhesive layer and the first transmissive adhesive layer.

15. The method of manufacturing the display panel according to claim 13, further comprising:
adhering a lower edge of the opaque adhesive layer that is not overlaid by the second transmissive adhesive layer to the substrate through a water-blocking adhesive after packaging the second transmissive adhesive layer on top of the opaque adhesive layer and the first transmissive adhesive layer.
